(19) United States
(12) Patent Application Publication
(10) Pub. No.: US 2018/0323045 A1
(43) Pub. Date: Nov. 8, 2018

(54) MANUFACTURING METHODS TO REDUCE SURFACE PARTICLE IMPURITIES AFTER A PLASMA PROCESS

(71) Applicant: Tokyo Electron Limited, Tokyo (JP)

(72) Inventors: Jason Marion, Glenville, NY (US); Yusuke Yoshida, Guilderland, NY (US); Brendan Bathrick, Poughkeepsie, NY (US); Sergey Voronin, Glenmont, NY (US); Alok Ranjan, Austin, TX (US)

(21) Appl. No.: 15/969,472

(22) Filed: May 2, 2018

Related U.S. Application Data
(60) Provisional application No. 62/500,261, filed on May 2, 2017.
(60) Provisional application No. 62/552,106, filed on Aug. 30, 2017.

(51) Int. Cl. H01J 37/32; H01L 21/67

(52) U.S. Cl. CPC H01J 37/32834; H01L 21/67069; H01L 21/6831; H01J 37/32816; H01J 37/32091

(57) ABSTRACT

Manufacturing methods are disclosed to reduce surface particle impurities after a plasma process (e.g., etch, deposition, etc.) by repelling particles trapped within particle wells to reduce surface particle impurities on microelectronic workpieces after termination of the plasma process. Rather than turn off pressure and source power at the termination of the plasma process, the disclosed embodiments first enter a sequence to adjust process parameters to repel particles in a particle well in order to reduce or eliminate the particle well prior to terminating the plasma process. During this particle repel sequence, certain disclosed embodiments adjust parameters to maintain an electrostatic field above the surface of the wafer utilizing low plasma density and ion energy conditions that help to repel particles from the microelectronic workpiece. The disclosed methods allow for the particle well to be exhausted well prior to the collapse of electrostatic forces when the plasma process is terminated.

### RELATED APPLICATIONS

This application claims priority to the following co-pending provisional applications: U.S. Provisional Patent Application Ser. No. 62/500,261, filed May 2, 2017, and entitled “METHOD FOR SURFACE PARTICLE REDUCTION VIA A PLASMA OFF PARTICLE REPEL SEQUENCE” and U.S. Provisional Patent Application Ser. No. 62/552,106, filed Aug. 30, 2017, and entitled “MANUFACTURING METHODS TO REDUCE SURFACE PARTICLE IMPURITIES AFTER A PLASMA PROCESS” which are hereby incorporated by reference in their entirety.

### BACKGROUND

The present disclosure relates to methods for processing microelectronic workpieces.

Semiconductor device formation involves a series of manufacturing techniques related to the formation, patterning and removal of a number of layers of material on a microelectronic workpiece, such as a substrate. In large-scale manufacturing of IC (integrated circuits), undesired particles within process chambers can cause problems related to yield loss. This potential yield loss makes particle management an extremely valuable asset to the overall process of manufacturing microelectronic workpieces.

During a plasma process (e.g., etch, deposition, etc.) for the manufacture of microelectronic workpieces, particles existing within the plasma receive a negative global charge. This negative global charge occurs for any electrically insulated object in a plasma due to the high mobility of electrons as compared to positive ions within the process chamber. The negatively charged particles can then become trapped in an electrostatic equilibrium at edges of plasma sheaths formed at the edges of the process chamber. These areas of trapped negatively charged particles are called “particle wells.” Particle wells occur when the many varying forces acting upon the negatively charged particles are balanced effectively trapping the particles within the particle wells. With plasma processing, the varying forces acting upon a particle include, but are not limited to, the following: gravitational, electrostatic, neutral and ion drag forces, thermophoretic and pressure gradient forces, and/or other forces.

The particle wells generated during a plasma process can lead to yield losses. These yield losses can occur because particles within a particle well that forms above a microelectronic workpiece (e.g., semiconductor wafer or substrate) during plasma processing will fall upon the surface of the microelectronic workpiece when the electrostatic force keeping the particle well suspended collapses at the termination of the plasma process. Because particle creation, accumulation and transport are process dependent, effective methods for exhausting particle wells are difficult to achieve. This problem is further complicated by throughput constraints and integrated circuit profile requirements for the manufacture of microelectronic workpieces.

FIG. 1 (Prior Art) is a cross-section diagram of an example embodiment 100 for a process chamber 104 with process space 110 where plasma source 102, such as a microwave (MW) plasma source and a radio frequency (RF) plasma source, has not been activated. A microelectronic workpiece 108 to be processed, such as a semiconductor wafer, is positioned above an RF electrode 106 within the process chamber 104. A focus ring 114 surrounds the microelectronic workpiece 108. Particles 112 represent particles that may release from the wall of the process chamber 104, from the focus ring 114, and/or from other exposed surfaces during the plasma process.

FIG. 2 (Prior Art) is a cross-section diagram of an example embodiment 200 for the process chamber 104 after the MW/RF plasma source 102 has been activated to generate a plasma bulk 204. A plasma sheath 202 also forms and exists adjacent the inner surfaces of the process chamber 104 as well as over the microelectronic workpiece 108 and focus ring 114. The particles 112 tend to be repelled from the wall of the process chamber 104 and from the focus ring 114. The particles 112 will then begin to cross the plasma sheath 202 and enter the plasma bulk 204. Initially, the particles 112 will tend to congregate at the edge between the plasma sheath 202 and the plasma bulk 204.

FIG. 3 (Prior Art) is a cross-section diagram of an example embodiment 300 for the process chamber 104 after the plasma process has proceeded for some period of time but has not yet been terminated. As shown, various forces act upon the particles, and some particles have now migrated further into the plasma bulk 204. Other particles have become trapped in a particle well 302 adjacent the edge of the microelectronic workpiece 108. As described above, the particle well 302 is formed due to an electric field gradient near the focus ring 114, and particles remain within the particle well 302 as forces acting on these particles reach an electrostatic equilibrium during the plasma process. The forces acting on these particles can include gravitational forces (F_{g}), ion drag forces (Fᵢₒₙ, F_{ionII}), electrostatic forces (F_{E}), and/or other forces.

When the plasma process is active, transport of particles is dominated by the electrostatic force and the ion drag forces. The electrostatic force accelerates the negatively charged particles toward the center of the electropositive plasma bulk 204 or toward local maxima in the plasma potential. The ion drag forces accelerate particles in the direction of net ion flux, which is generally towards the boundaries of the plasma bulk 204. In low electric fields (e.g., within the middle of the plasma bulk 204), the viscous ion drag force exceeds the electrostatic force, and the particles are accelerated toward the boundaries of the plasma bulk 204. In large electric fields (e.g., near the plasma sheath 202), the electrostatic force exceeds the ion drag force and the particles are forced into the plasma bulk 204. The particles will accumulate where the forces balance, which is typically near the plasma sheath 202 and near the edge of the microelectronic workpiece 108 within the particle well 302.

FIG. 4 (Prior Art) is a process control diagram of an example embodiment 400 for pressure 402, microwave (MW) source power (or other source power) 404, and radio frequency (RF) bias power 406 used for an example plasma process (e.g., etch, deposition, etc.). Region A represents normal processing 408 that eventually produces the particle well 302 shown in FIG. 3 (Prior Art). Region B represents a dechucking process 410 after the plasma process is terminated, as indicated by dashed line 412. The microelectronic workpiece 108 can then be removed from the process chamber 104, if desired, such as by removing the microelectronic workpiece 108 from a chuck within the process chamber 104. For the example embodiment 400, the pressure 402 is set to 150 mT (milli-Torr) during normal processing 408, is set to 0 mT when the plasma process is terminated at dashed line 412, and remains at 0 mT during the dechucking process 410. The MW source power (or other source power) 404 is set to 3000 W (watts) during normal processing 408, is set to 0 W when the plasma process is terminated, and remains at 0 W during the dechucking process 410. The RF bias power 406 is set to 100 W during normal processing 408, is set to 0 W when the plasma process is terminated, and remains at 0 W during the dechucking process 410.

FIG. 5A (Prior Art) is a cross-section diagram of an example embodiment 500 for the process chamber 104 after the plasma process has been terminated. This termination tends to remove most of the forces acting on the particles within the process space 110 leaving the gravitation force (F_{g}). As such, the particles within the particle well 302 as shown in FIG. 3 will tend to fall within a ring 502 on the top surface of the microelectronic workpiece 108. Other particles 504 may also fall on the wafer 108, although the number of particles within ring 502 will often be significantly higher density than the other particles 504. The particles 502/504 that land on the microelectronic workpiece 108 after termination of the plasma process can lead to yield losses as indicated above.

FIG. 5B (Prior Art) is a top view diagram of an example embodiment 550 for particles falling on the microelectronic workpiece 108 as a result of the prior plasma process described with respect to of FIGS. 1-4 and 5A (Prior Art). As can be seen for this representative example, a large number of particles associated with the particle well 302 have fallen on the edge of the microelectronic workpiece 108.

### SUMMARY

Manufacturing methods are disclosed to reduce surface particle impurities after a plasma process (e.g., etch, deposition, etc.).

For one embodiment, a method of processing a microelectronic workpiece is disclosed including performing a plasma process on a microelectronic workpiece within a process chamber where the plasma process in part causes particles to be in electrostatic equilibrium within a particle well at an edge of a plasma sheath above a surface of the microelectronic workpiece, and before terminating the plasma process, performing a sequence to adjust process parameters to repel particles within the particle well away from the surface of the microelectronic workpiece. After this particle repel sequence is performed, the method also includes terminating the plasma process.

In additional embodiments, the plasma process includes at least one of a plasma etch process or a plasma enhanced deposition process. In further embodiments, the method includes exhausting the repelled particles along with gases during the sequence. In still further embodiments, the method includes performing the sequence for a predetermined period of time.

In additional embodiments, the sequence includes maintaining an electrostatic field above the surface of the microelectronic workpiece. In further embodiments, the maintaining includes generating a low plasma density condition and a low ion energy condition for the particle well for a predetermined period of time to allow the plasma sheath to extinguish before terminating the plasma process. In still further embodiments, the maintaining further includes generating a low pressure condition for the predetermined period of time.

In additional embodiments, a plurality of microelectronic workpieces are processed. In further embodiments, the performing of the sequence does not degrade a throughput or a yield for the processing of the plurality of microelectronic workpieces.

In additional embodiments, the process parameters that are adjusted include at least one of pressure, radio frequency (RF) bias power, or source power. In further embodiments, the process parameters include pressure; the pressure during the sequence is between 1 mT and 300 mT; and the pressure during the plasma process is between 1 mT and 1000 mT. In still further embodiments, the pressure is reduced during the sequence to reduce particle collisions and thereby allow particles within the particle well to be exhausted. In further embodiments, the process parameters include RF bias power; the RF bias power during the sequence and is between 1 W and 300 W; and the RF bias power during the plasma process is between 5 W and 5000 W. In still further embodiments, the RF bias power is maintained during the sequence to expand the plasma sheath and repel particles from the microelectronic workpiece. In still further embodiments, the process parameters include source power, and the source power during the sequence and is set to 0 W. In further embodiments, the process parameters include source power, and the source power is adjusted during the sequence to be a value less than the value used during the plasma process. In still further embodiments, the source power is set to 0 W during the sequence.

In additional embodiments, the microelectronic workpiece includes a semiconductor substrate. In further embodiments, the semiconductor substrate includes a semiconductor wafer. In still further embodiments, the method also includes removing the semiconductor wafer from a chuck after terminating the plasma process.

Different or additional features, variations, and embodiments can be implemented, if desired, and related systems and methods can be utilized, as well.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIG. 1 (Prior Art) is a cross-section diagram of an example embodiment for a process chamber where a plasma source, such as a microwave (MW) plasma source and/or a radio frequency (RF) plasma source, has not been activated.

FIG. 2 (Prior Art) is a cross-section diagram of an example embodiment for the process chamber after the MW/RF plasma source has been activated to generate a plasma bulk.

FIG. 3 (Prior Art) is a cross-section diagram of an example embodiment for the process chamber after the plasma process has proceeded for some period of time but has not yet been terminated.

FIG. 4 (Prior Art) is a process control diagram of an example embodiment for process parameters used for an example plasma process.

FIG. 5A (Prior Art) is a cross-section diagram of an example embodiment for the process chamber after the plasma process has been terminated.

FIG. 5B (Prior Art) is a top view diagram of an example embodiment for particles falling on the microelectronic workpiece as a result for the plasma process of FIGS. 1-4 and 5A (Prior Art).

FIG. 6 is a process flow diagram of an example embodiment according to the disclosed embodiments that include a particle repel sequence prior to termination of the plasma process.

FIG. 7 is a process control diagram of an example embodiment for process parameters used for an example plasma process where a particle repel sequence has been included to reduce or eliminate particle wells.

FIG. 8 is a cross-section diagram of an example embodiment for the process chamber during the particle repel sequence.

FIG. 9A is a cross-section diagram of an example embodiment for the process chamber after the plasma process has been terminated following the particle repel sequence.

FIG. 9B is a top view diagram of an example embodiment for particles falling on the microelectronic workpiece as a result for the plasma process of FIGS. 6-8 and 9A.

FIG. 10 is a block diagram of an example embodiment for a plasma processing apparatus for the embodiments described herein.

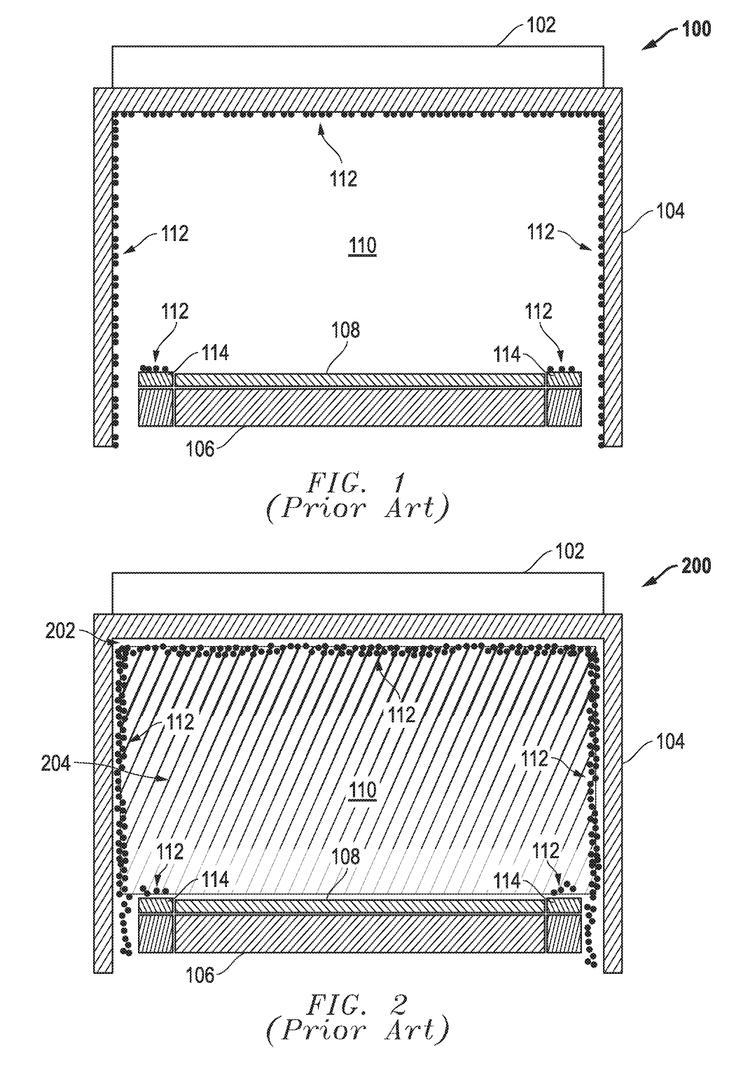

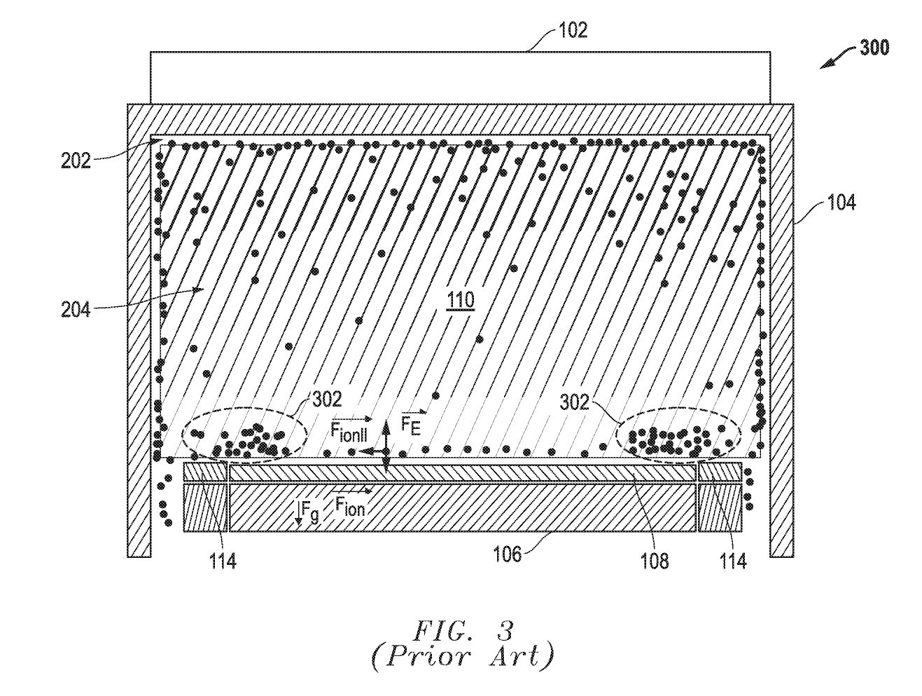

### DETAILED DESCRIPTION

Manufacturing methods are disclosed to reduce surface particle impurities after a plasma process (e.g., etch, deposition, etc.).

Disclosed embodiments effectively repel particles trapped within particle wells to reduce surface particle impurities on microelectronic workpieces after termination of a plasma process (e.g., etch, deposition, etc.). In particular, rather than turn off pressure and the MW/RF source and/or bias power at the termination of the plasma process, the disclosed embodiments first enter a sequence to adjust process parameters to repel particles within a particle well in order to reduce or eliminate the particle well prior to terminating the plasma process. During this particle repel sequence, certain disclosed embodiments maintain an electrostatic field above the surface of the wafer utilizing low plasma density and ion energy conditions that are unlikely to affect or degrade integrated circuit profiles. This particle repel sequence also helps to exhaust the particle well prior to the collapse of electrostatic forces when the plasma process is terminated. Further, when a plurality of microelectronic workpieces are processed, the disclosed embodiments do not degrade a throughput or a yield for the processing of the plurality of microelectronic workpieces. In addition, although the examples described herein are primarily with respect to a plasma etch process, the techniques described herein to repel particles away from the microelectronic workpiece can be used prior to termination of other plasma processes, such as a plasma enhanced deposition process (e.g., plasma enhanced chemical vapor deposition) and/or other plasma processes. Other advantages and variations can also be provided while still taking advantage of the particle repel sequence techniques described herein.

FIG. 6 is a process flow diagram of an example embodiment 600 according to the disclosed embodiments. In block 602, a plasma process (e.g., etch, deposition, etc.) is performed on a microelectronic workpiece 108 with a process chamber 104. In block 604, a particle repel sequence is performed to repel particles within a particle well 302 away from the surface of the microelectronic workpiece 108 prior to the plasma processing being terminated. In block 606, these particles are then exhausted along with gases within the process chamber 104 during an exhaust phase. As described herein, by lowering the pressure and keeping the particles within the particle well 302 away from the microelectronic workpiece 108, these particles can be effectively evacuated or exhausted from the process chamber 104 while new particles are not formed in absence of major process reactions during the particle repel sequence. In block 608, the plasma process is terminated. As described herein, the particle repel sequence helps to exhaust particle wells prior to the collapse of electrostatic forces when the plasma process is terminated.

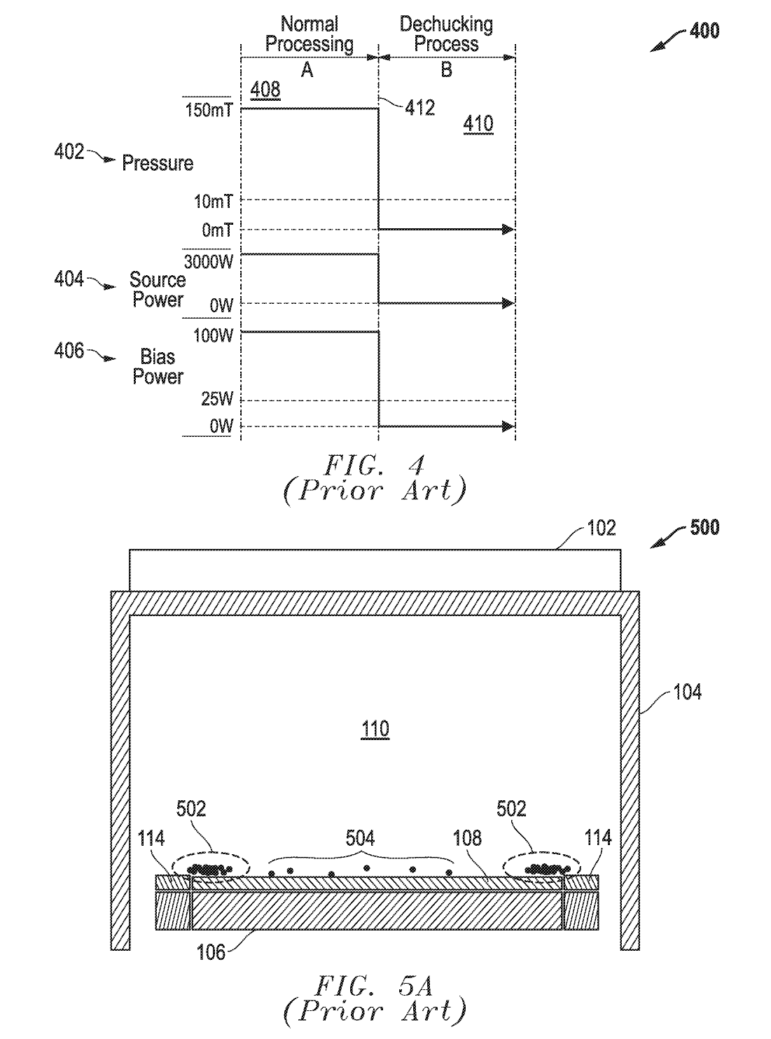

FIG. 7 is a process control diagram of an example embodiment 700 for pressure 402, microwave (MW) source power (or other source power) 404, and radio frequency (RF) bias power 406 used for an example plasma process (e.g., etch, deposition, etc.) where a particle repel sequence 702 has been included to reduce or eliminate particle wells. Similar to embodiment 400 of FIG. 4 (Prior Art), Region A for embodiment 700 represents normal processing 408 that eventually produces the particle well 302 shown in FIG. 3 (Prior Art). In contrast to embodiment 400 of FIG. 4 (Prior Art), embodiment 700 of FIG. 7 includes a particle repel sequence 702 in Region B that helps to reduce or remove the particle well 302 of FIG. 3 (Prior Art) prior to the termination of the plasma process as indicated by dashed line 402 and the start of dechucking process 410 in Region C. The dechucking process 410 in Region C of FIG. 7 matches the dechucking process 410 of FIG. 4 (Prior Art).

For the example embodiment 700, the pressure 402 is set to 150 mT (milli-Torr) during normal processing 408, is set to 10 mT during the particle repel sequence 702 between dashed line 704 and dashed line 402, and is set to 0 mT when the plasma process is terminated upon entering the dechucking process 410. The MW source power 404 is set to 3000 W (watts) during normal processing 408, is set to 0 W during the particle repel sequence 702, and remains at 0 W after the plasma process is terminated for the dechucking process 410. The RF bias power 406 is set to 100 W during normal processing 408, is set to 25 W during the particle repel sequence 702, and is set to 0 W when the plasma process is terminated upon entering the dechucking process 410. It is noted that the RF bias power 406 represents the RF power applied to the microelectronic workpiece 108 through the RF electrode 106. Although the source power 404 is referred to in examples herein as a microwave (MW) source power, other source power techniques can also be used, such as RF source power and/or other source power.

It is noted that the particle repel sequence 702 can be performed for a predetermined period of time to allow the plasma sheath to extinguish before terminating the plasma process. During this predetermined period of time, an electrostatic field is maintained above the surface of the microelectronic workpiece. For example, the electrostatic field can be maintained by generating a low plasma density condition and a low ion energy condition for the particle well. Further, a low pressure condition can also be used. For certain example embodiments using a particle repel sequence 702, the MW source power 404 is turned off, the pressure 402 is reduced to 5-15 percent of the pressure level during the normal processing 408, and the RF bias power 406 is set to between 1 W and 300 W. As a further example, the pressure 402 during the particle repel sequence 702 can be in a range from between 1 mT to 300 mT, and the pressure 402 during normal processing 408 can be in a range from between 1 mT to 1000 mT. Further, the RF bias power 406 during the particle repel sequence 702 can be in a range from between 1 W to 300 W, and the RF bias power 406 during the normal processing 408 (if used) can be in a range from between 5 W to 5000 W. It is also noted that the RF bias power 406 can also be turned off and not used during normal processing 408, or only used for a portion of the normal processing 408, if desired. As described herein, the absence of the MW source power (or other source power) 404 with reduced levels for the pressure 402 while applying RF bias power 406 helps to maintain an electrostatic field that allows particles within the particle well 302 to be repelled away from the surface of the microelectronic workpiece 108 and to be exhausted along with other gases within the process chamber 104. In addition, different and/or additional process parameters can be used, while still taking advantage of the techniques described herein, as long as the particle repel sequence 702 maintains low ion and viscous drag forces and maintains a sufficient electrostatic force so that particles within the particle well 302 can be repelled from the workpiece 108 and exhausted from the process chamber 104.

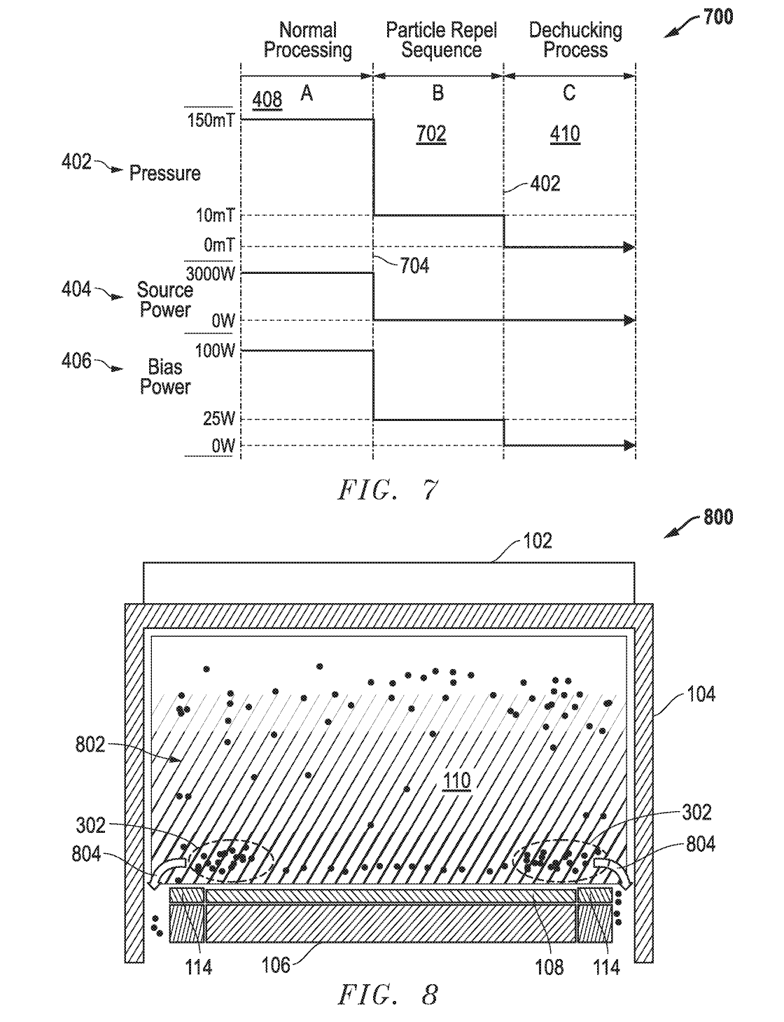

FIG. 8 is a cross-section diagram of an example embodiment 800 for the process chamber 104 during the particle repel sequence 702 for embodiment 700 of FIG. 7. As described herein, the introduction of a particle repel sequence 702 helps to reduce or remove particles from the particle well 302 suspended over the edges of the microelectronic workpiece 108. The adjusted plasma bulk 802 is now lower energy, and forces acting on the particles within the particle well 302 allow these particles to be repelled away from the microelectronic workpiece 108. As represented by arrows 804, these repelled particles within the particle well 302 are exhausted along with process gas from the process space 110 for the process chamber 104.

The particle repel sequence 702 of FIG. 7 provides for low plasma density and low pressure while maintaining an electric field. The low plasma density is achieved by removing the source power for the MW source power 404 (or RF bias power 406) and setting it to 0 W for the particle repel sequence 702. The electric field is maintained by reducing the RF bias power 406 to 25 W rather than turning it off during the particle repel sequence 702. The low pressure is achieved by reducing the pressure to 10 mT rather than turning it off during the particle repel sequence. Generating low plasma density while maintaining an electric field effectively increases or expands the plasma sheath and repels particles from the microelectronic workpiece 108 and the focus ring 114. Also during this particle repel sequence 702, particle generation within the process space 110 is reduced or eliminated by the change in process parameters. Further, the low pressure effectively reduces particle collisions thereby reducing ion and viscous drag forces and allowing particles to be exhausted along with the process gas being exhausted from the process chamber 104.

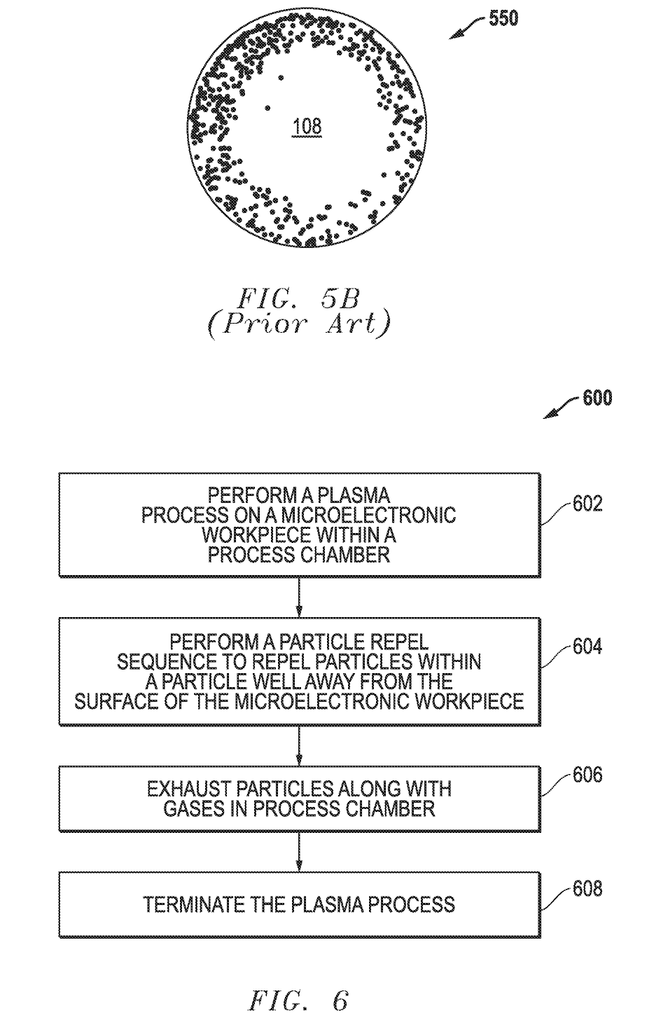

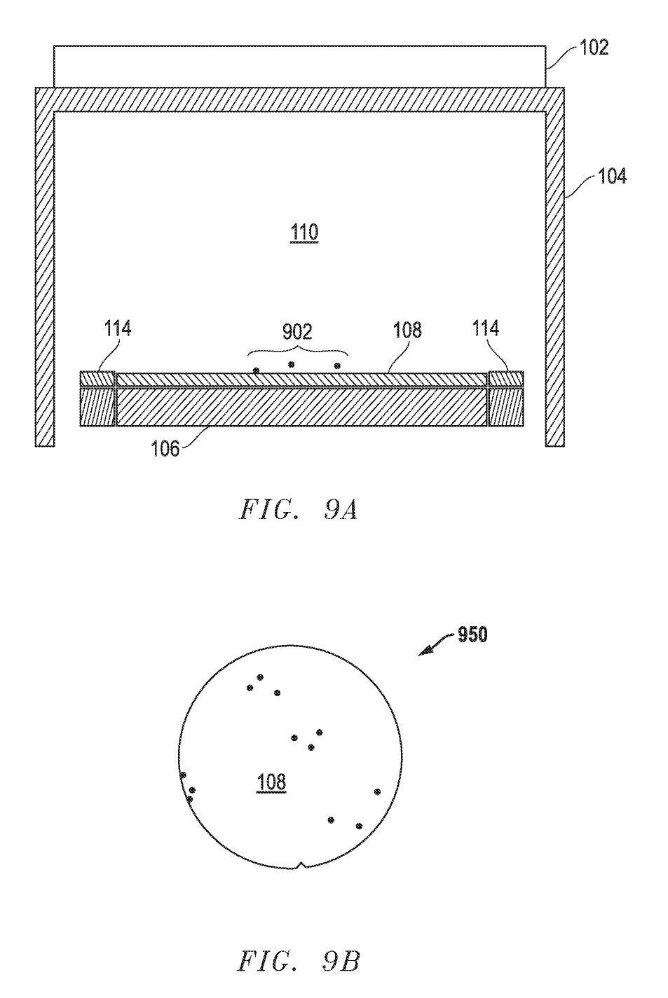

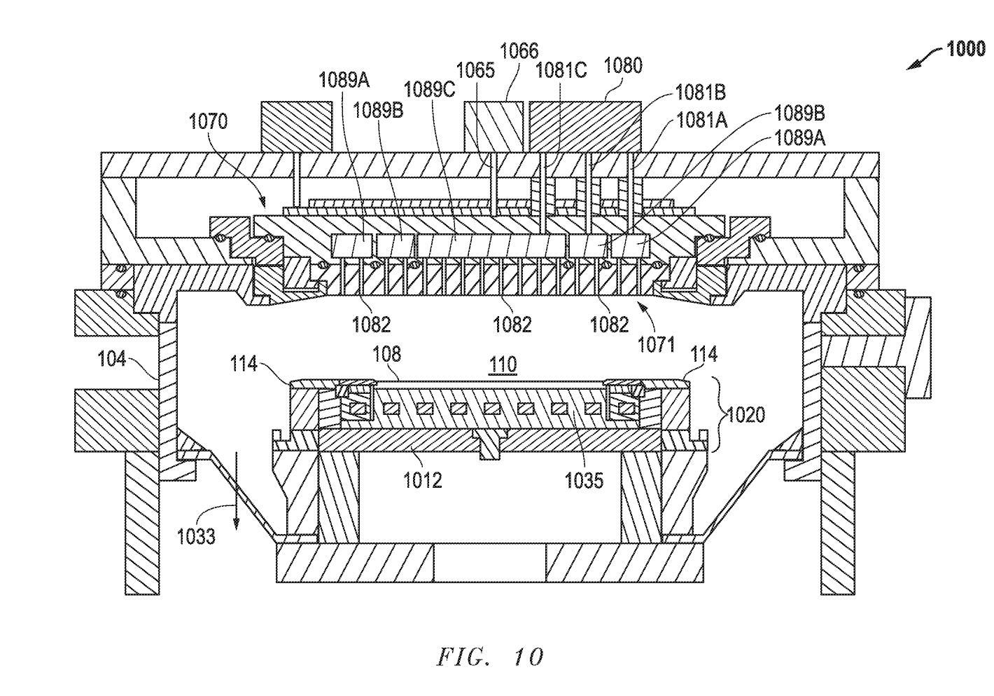

FIG. 9A is a cross-section diagram of an example embodiment 900 for the process chamber 104 after the plasma process has been terminated following the particle repel sequence 702. This deactivation tends to remove most of the forces acting on the particles within the process space 110 leaving the gravitation force (F_{g}). However, because particles within the particle well 302 have been reduced by the particle repel sequence, very few if any particles remain with the particle well 302 to fall on the top surface of the wafer 108. Although other particles 902 may still fall on the wafer 108, these are significantly reduced in number as compared to particles 502 and 504 in FIG. 5A (Prior Art).

FIG. 9B is a top view diagram of an example embodiment 950 for particles falling on the microelectronic workpiece 108 as a result of the plasma process described with respect to of FIGS. 6-8 and 9A. As can be seen for this representative example, a relatively small number of particles have fallen on the edge of the microelectronic workpiece 108, particularly as compared to FIG. 5B (Prior Art).

FIG. 10 is a block diagram of an example embodiment 1000 for a plasma processing apparatus for the embodiments described herein. More particularly, FIG. 10 illustrates one example embodiment for a plasma processing apparatus merely for illustrative purposes that can be used to implement the plasma processing techniques described herein. It will be recognized that other plasma processing systems and other plasma processing systems may equally implement the techniques described herein. For the example embodiment 1000 of FIG. 10, a schematic cross-sectional view is provided for a capacitively coupled plasma processing apparatus including a process space 110 for an process chamber 104 for microelectronic workpieces. Alternative plasma process apparatus may also be utilized, as desired.

The plasma processing apparatus 1000 can be used for multiple operations including ashing, etching, deposition, cleaning, plasma polymerization, plasma-enhanced chemical vapor deposition (PECVD), atomic layer deposition (ALD) and so forth. The structure of a plasma processing apparatus 1000 is well known, and the particular structure provided herein is merely exemplary. Plasma etch processing can be executed within process chamber 104, which can be a vacuum chamber made of a metal such as aluminum or stainless steel. The process chamber 104 defines a processing vessel providing a process space 110 for plasma generation. An inner wall of the processing vessel can be coated with alumina, yttria, or other protectant. The processing vessel can be cylindrical in shape or have other geometric configurations.

At a lower, central area within the process chamber 104, a susceptor 1012 (which can be disc-shaped) can serve as a mounting table on which a microelectronic workpiece 108, such as a semiconductor wafer, can be mounted. Microelectronic workpiece 108 can be moved into the process chamber 104 through a loading/unloading port and gate valve. Susceptor 1012 forms part of a lower electrode assembly 1020 as an example of a second electrode acting as a mounting table for mounting microelectronic workpiece 108 thereon. The susceptor 1012 can be formed of, e.g., an aluminum alloy. Susceptor 1012 is provided thereon with an electrostatic chuck (as part of the lower electrode assembly) for holding the microelectronic workpiece 108. The electrostatic chuck is provided with an electrode 1035. Electrode 1035 is electrically connected to direct current (DC) power source, not shown. The electrostatic chuck attracts the microelectronic workpiece 108 thereto via an electrostatic force generated when DC voltage from the DC power source is applied to the electrode 1035. The susceptor 1012 can be electrically connected with a high-frequency power source via a matching unit. For other embodiments and process chambers, two or more power sources can be used and connected to electrode 1035 and/or other electrodes within the process chambers. This high-frequency power source (a second power source) can output a high-frequency voltage in a range from, for example, 2 MHz to 20 MHz. Applying high frequency bias power causes ions, in plasma generated in the process chamber 110, to be attracted to microelectronic workpiece 108. A focus ring assembly 114 is provided on an upper surface of the susceptor 1012 to surround the electrostatic chuck.

An exhaust path 1033 can be formed through one or more exhaust ports (not shown) which connect to a gas exhaust unit. The gas exhaust unit can include a vacuum pump such as a turbo molecular pump configured to pump out the plasma processing space within the process chamber 104 to a desired vacuum condition. The gas exhaust unit evacuates the inside of the process chamber 104 thereby depressurizing the inner pressure thereof down to the desired degree of vacuum.

An upper electrode assembly 1070 is an example of a first electrode and is positioned vertically above the lower electrode assembly 1020 to face the lower electrode assembly 1020 in parallel. The plasma generation space or process space 110 is defined between the lower electrode assembly 1020 and the upper electrode assembly 1070. The upper electrode assembly 1070 includes an inner upper electrode 1071, having a disk shape, and an outer upper electrode which may be annular and surrounding a periphery of the inner upper electrode 1071. The inner upper electrode 1071 also functions as a processing gas inlet for injecting a specific amount of processing gas into the process space 110 above microelectronic workpiece 108 mounted on the lower electrode assembly 1020. The upper electrode assembly 1070 thereby forms a shower head. More specifically, the inner upper electrode 1071 includes gas injection openings 1082.

The upper electrode assembly 1070 may include one or more buffer chamber(s) 1089A, 1089B, and 1089C. The buffer chambers are used for diffusing process gas and can define a disk-shaped space. Processing gas from a process gas supply system 1080 supplies gas to the upper electrode assembly 1070. The process gas supply system 1080 can be configured to supply a processing gas for performing specific processes, such as film-forming, etching, and the like, on the microelectronic workpiece 108. The process gas supply system 1080 is connected to gas supply lines 1081A, 1081B, and 1081C forming a processing gas supply path. The gas supply lines are connected to the buffer chambers of the inner upper electrode 1071. The processing gas can then move from the buffer chambers to the gas injection openings 1082 at a lower surface thereof. A flow rate of processing gas introduced into the buffer chambers 1089A-C can be adjusted by, e.g., by using a mass flow controller. Further, the processing gas introduced is discharged from the gas injection openings 1082 of the electrode plate (showerhead electrode) to the process space 110. The inner upper electrode 1071 functions in part to provide a showerhead electrode assembly.

As shown in FIG. 10, three buffer chambers 1089A, 1089B, and 1089C are provided corresponding to edge buffer chamber 1089A, middle buffer chamber 1089B, and center buffer chamber 1089C. Similarly, gas supply lines 1081A, 1081B, and 1081C may be configured as edge gas supply line 1081A, middle gas supply line 1081B and center gas supply line 1081C. The buffer chambers are provided in a manner corresponding to different localized regions of the substrate in this case edge, middle and center. These regions may correspond to specific plasma process conditions for localized regions of the microelectronic workpiece 108. It will be recognized that the use of three localized regions is merely exemplary. Thus, the plasma processing apparatus may be configured to provided localize plasma process conditions on any number of regions of the substrate. It is further again noted that any of a variety of configurations may be utilized

The upper electrode assembly 1070 is electrically connected with a high-frequency power source (not shown) (first high-frequency power source) via a power feeder 1065 and a matching unit 1066. The high-frequency power source can output a high-frequency voltage having a frequency of 40 MHz (megahertz) or higher (e.g., 60 MHz), and/or can output a very high frequency (VHF) voltage having a frequency of 30-300 MHz. This power source can be referred to as the main power supply as compared to a bias power supply. It is noted for certain embodiments there is no power source for the upper electrodes, and two power sources are connected to the bottom electrode. Other variations could also be implemented.

Components of the plasma processing apparatus can be connected to, and controlled by, a control unit, which in turn can be connected to a corresponding memory storage unit and user interface (all not shown). Various plasma processing operations can be executed via the user interface, and various plasma processing recipes and operations can be stored in a storage unit. Accordingly, a given substrate can be processed within the plasma process chamber with various microfabrication techniques. In operation, the plasma processing apparatus uses the upper and lower electrodes to generate a plasma in the process space 110. This generated plasma can then be used for processing a target substrate (such as microelectronic workpiece 108 or any material to be processed) in various types of treatments such as plasma etching, chemical vapor deposition, treatment of semiconductor material, glass material and large panels such as thin-film solar cells, other photovoltaic cells, and organic/inorganic plates for flat panel displays, etc.

It is noted that reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

“Microelectronic workpiece” as used herein generically refers to the object being processed in accordance with the invention. The microelectronic workpiece may include any material portion or structure of a device, particularly a semiconductor or other electronics device, and may, for example, be a base substrate structure, such as a semiconductor substrate or a layer on or overlying a base substrate structure such as a thin film. Thus, workpiece is not intended to be limited to any particular base structure, underlying layer or overlying layer, patterned or unpatterned, but rather, is contemplated to include any such layer or base structure, and any combination of layers and/or base structures. The description below may reference particular types of substrates, but this is for illustrative purposes only and not limitation.

The term “substrate” as used herein means and includes a base material or construction upon which materials are formed. It will be appreciated that the substrate may include a single material, a plurality of layers of different materials, a layer or layers having regions of different materials or different structures in them, etc. These materials may include semiconductors, insulators, conductors, or combinations thereof. For example, the substrate may be a semiconductor substrate, a base semiconductor layer on a supporting structure, a metal electrode or a semiconductor substrate having one or more layers, structures or regions formed thereon. The substrate may be a conventional silicon substrate or other bulk substrate comprising a layer of semi-conductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

Systems and methods for processing a microelectronic workpiece are described in various embodiments. One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Further modifications and alternative embodiments of the described systems and methods will be apparent to those skilled in the art in view of this description. It will be recognized, therefore, that the described systems and methods are not limited by these example arrangements. It is to be understood that the forms of the systems and methods herein shown and described are to be taken as example embodiments. Various changes may be made in the implementations. Thus, although the inventions are described herein with reference to specific embodiments, various modifications and changes can be made without departing from the scope of the present inventions. Accordingly, the specification and figures are to be regarded in an illustrative rather than a restrictive sense, and such modifications are intended to be included within the scope of the present inventions. Further, any benefits, advantages, or solutions to problems that are described herein with regard to specific embodiments are not intended to be construed as a critical, required, or essential feature or element of any or all the claims.

What is claimed is:

1. A method of processing a microelectronic workpiece, comprising:
performing a plasma process on a microelectronic workpiece within a process chamber, the plasma process in part causing particles to be in electrostatic equilibrium within a particle well at an edge of a plasma sheath above a surface of the microelectronic workpiece;
before terminating the plasma process, performing a sequence to adjust process parameters to repel particles within the particle well away from the surface of the microelectronic workpiece; and
terminating the plasma process.

2. The method of claim 1, wherein the plasma process comprises at least one of a plasma etch process or a plasma enhanced deposition process.

3. The method of claim 1, wherein the sequence comprises maintaining an electrostatic field above the surface of the microelectronic workpiece.

4. The method of claim 3, wherein the maintaining comprises generating a low plasma density condition and a low ion energy condition for the particle well for a predetermined period of time to allow the plasma sheath to extinguish before terminating the plasma process.

5. The method of claim 4, wherein the maintaining further comprises generating a low pressure condition for the predetermined period of time.

6. The method of claim 1, wherein a plurality of microelectronic workpieces are processed.

7. The method of claim 6, wherein the performing of the sequence does not degrade a throughput or a yield for the processing of the plurality of microelectronic workpieces.

8. The method of claim 1, further comprising exhausting the repelled particles along with gases during the sequence.

9. The method of claim 1, wherein the process parameters comprise at least one of pressure, radio frequency (RF) bias power, or source power.

10. The method of claim 9, wherein the process parameters comprise pressure, and wherein the pressure during the sequence is between 1 mT and 300 mT, and wherein the pressure during the plasma process is between 1 mT and 1000 mT.

11. The method of claim 10, wherein the pressure is reduced during the sequence to reduce particle collisions and thereby allow particles within the particle well to be exhausted.

12. The method of claim 9, wherein the process parameters comprise RF bias power, and wherein the RF bias power during the sequence and is between 1 W and 300 W, and wherein the RF bias power during the plasma process is between 5 W and 5000 W.

13. The method of claim 12, wherein the RF bias power is maintained during the sequence to expand the plasma sheath and repel particles from the microelectronic workpiece.

14. The method of claim 13, wherein the process parameters further comprise source power, and wherein the source power during the sequence is set to 0 W.

15. The method of claim 9, wherein the process parameters comprise source power, and wherein the source power is adjusted during the sequence to be a value less than the value used during the plasma process.

16. The method of claim 15, wherein the source power is set to 0 W during the sequence.

17. The method of claim 1, further comprising performing the sequence for a predetermined period of time.

18. The method of claim 1, wherein the microelectronic workpiece comprises a semiconductor substrate.

19. The method of claim 18, wherein the semiconductor substrate comprises a semiconductor wafer.

20. The method of claim 19, further comprising removing the semiconductor wafer from a chuck after terminating the plasma process.
